(19) United States
(12) Patent Application Publication
(10) Pub. No.: US 2022/0254771 A1
(43) Pub. Date: Aug. 11, 2022

(54) SEMICONDUCTOR CIRCUIT AND MANUFACTURING METHOD FOR THE SAME

(71) Applicant: MACRONIX INTERNATIONAL CO., LTD., Hsinchu (TW)

(72) Inventor: Shih-Yu WANG, Taipei City (TW)

(21) Appl. No.: 17/168,210

(22) Filed: Feb. 5, 2021

(51) Int. Cl. H01L 27/02

(52) U.S. Cl. CPC H01L 27/0255

(57) ABSTRACT

A semiconductor circuit and a manufacturing method for the same are provided. The semiconductor circuit includes an electrostatic discharge protection circuit. The electrostatic discharge protection circuit includes an N-type region, a P-type well, a first P-type element and a first N-type element. The P-type well is in the N-type region. The first P-type element is in the N-type region. The N-type region is continuously connected between the P-type well and the first P-type element. The first N-type element is in the P-type well.

### BACKGROUND

### Technical Field

The disclosure relates to a semiconductor circuit and a manufacturing method for the same.

### Description of the Related Art

Electrostatic discharge (ESD) includes the sudden flow of electricity between two electrically charged objects caused by contact, an electrical short, or dielectric breakdown. ESD events can occur for an extremely short period of time, e.g., on the order of several nanoseconds, during which very high currents may be generated. When an ESD event occurs in a semiconductor circuit, such high currents, which may reach several amperes, have the potential to irreversibly damage an internal circuit. To protect the internal circuit from damage resulting from ESD events, an electrostatic discharge protection circuit may be provided that discharges the electrostatic current.

Some tests are usually performed to a semiconductor integrated circuit. For example, in latch-up tests, a positive voltage, a positive current, and a genitive current are provided to a conductive pad of a semiconductor circuit. In a negative current test, a negative voltage is applied to the conductive pad so as to extracts a current from a ground terminal of the semiconductor circuit. However, an external negative voltage applied to the conductive pad may affect the internal circuit of the semiconductor circuit and causes malfunction of the internal circuit.

The electrostatic discharge protection circuit occupies an additional layout area, and it limits an improvement for a transistor density. Therefore, it is desired to decrease an area for the electrostatic discharge protection circuit.

### SUMMARY

The present disclosure relates to a semiconductor circuit and a manufacturing method for the same.

According to an embodiment, a semiconductor circuit is provided. The semiconductor circuit comprises an electrostatic discharge protection circuit. The electrostatic discharge protection circuit comprises an N-type region, a P-type well, a first P-type element and a first N-type element. The P-type well is in the N-type region. The first P-type element is in the N-type region. The N-type region is continuously connected between the P-type well and the first P-type element. The first N-type element is in the P-type well.

According to another embodiment, a manufacturing method for a semiconductor circuit is provided, which comprises the following steps. A N-type region is formed. A P-type well is formed. The P-type well is in the N-type region. A first P-type element is formed in the N-type region. A first N-type element is formed in the P-type well. The semiconductor circuit comprises an electrostatic discharge protection circuit. The electrostatic discharge protection circuit comprises the N-type region, the P-type well, the first P-type element and the first N-type element. The N-type region is continuously connected between the P-type well and the first P-type element.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1A illustrates an electrostatic discharge protection circuit of a semiconductor circuit and a manufacturing method for which in an embodiment.

FIG. 1B illustrates an equivalent circuit of an electrostatic discharge protection circuit.

FIG. 2 illustrates an electrostatic discharge protection circuit of a semiconductor circuit and a manufacturing method for which in another embodiment.

FIG. 3 illustrates a semiconductor circuit in an embodiment.

FIG. 4 illustrates a semiconductor circuit in a comparative example.

FIG. 5 illustrates a semiconductor circuit in another comparative example.

### DETAILED DESCRIPTION

The illustrations may not be necessarily drawn to scale, and there may be other embodiments of the present disclosure which are not specifically illustrated. Thus, the specification and the drawings are to be regard as an illustrative sense rather than a restrictive sense. Moreover, the descriptions disclosed in the embodiments of the disclosure such as detailed construction, manufacturing steps and material selections are for illustration only, not for limiting the scope of protection of the disclosure. The steps and elements in details of the embodiments could be modified or changed according to the actual needs of the practical applications. The disclosure is not limited to the descriptions of the embodiments. The illustration uses the same/similar symbols to indicate the same/similar elements.

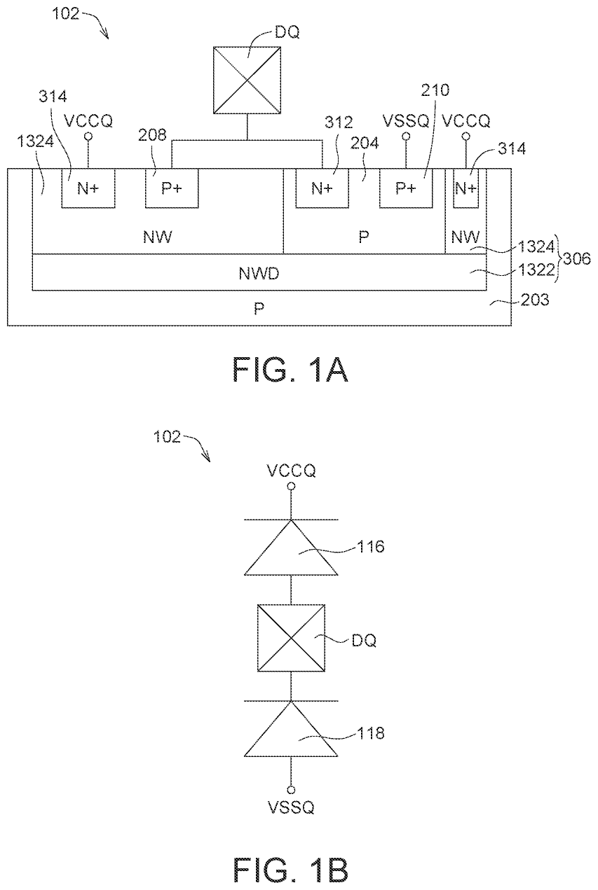

FIG. 1A is referred to, which illustrates an electrostatic discharge protection circuit 102 of a semiconductor circuit and a manufacturing method for which in an embodiment. A P-type well 204 is in an N-type region 306. The N-type region 306 comprises a first N-type well (NW) 1322 and a second N-type well (NWD) 1324 electrically connected with the first N-type well 1322. The second N-type well 1324 may be adjoined on the first N-type well 1322. The first N-type well 1322 may have an N-type dopant concentration higher than an N-type dopant concentration of the second N-type well 1324. In a top view, the second N-type well 1324 may have a dosed ring shape profile (not shown). The second N-type well 1324 is on a sidewall of the P-type well 204. The sidewall of the P-type well 204 may be surrounded by the second N-type well 1324. The P-type well 204 may be formed by an implanting process. A profile of the P-type well 204 may be defined by the first N-type well 1322 and the second N-type well 1324. The first N-type well 1322 under the P-type well 204 may be adjoined with all of a lower surface of the second N-type well 1324. In embodiments, the N-type region 306 is continuously connected between the P-type well 204 and a first P-type element 208. The first P-type element 208 is in the second N-type well 1324. A second P-type element 210 is in the P-type well 204, The first P-type element 208 and the second P-type element 210 may have a P-type dopant concentration higher than a P-type dopant concentration of the P-type well 204. The first P-type element 208 and the second P-type element 210 may be P-type impurity heavily doped (P+) elements. A first N-type element 312 is in the P-type well 204. A second N-type element 314 is in the second N-type well 1324. An N-type impurity concentration of the first N-type element 312 and an N-type impurity concentration of the second N-type element 314 may be higher than an N-type impurity concentration of the first N-type well 1322, and higher than an N-type impurity concentration of the second N-type well 1324. The first N-type element 312 and the second N-type element 314 may be N-type impurity heavily doped (N+) elements. The first P-type element 208 and the first N-type element 312 are electrically connected to a conductive pad DQ (such as an output/input pad (I/O pad)). The second N-type element 314 is electrically connected to a signal input terminal VCCQ. The second P-type element 210 is electrically connected to a ground terminal VSSQ.

In embodiments, the N-type components and the P-type components of the electrostatic discharge protection circuit 102 may be formed by doping impurities by implanting processes. For example, the first N-type well 1322 may be formed by an implanting process (or first implanting process) for doping an N-type impurity into a P-type region 203 (such as a P-type substrate or a P-type well) exposed by an opening of a mask layer (or first mask layer, not shown). The second N-type well 1324 may be formed by another implanting process (or second implanting process) for doping an N-type impurity into the P-type region 203 exposed by an opening of another mask layer (or second mask layer, not shown). The first P-type element 208 may be formed by implanting processes for doping a P-type impurity into the second N-type well 1324. The second P-type element 210 may be formed by an implanting process for doping a P-type impurity into the P-type well 204. The first P-type element 208 and the second P-type element 210 may be formed at the same time. The first N-type element 312 may be formed by an implanting process for doping an N-type impurity into the P-type well 204. The second N-type element 314 may be formed by an implanting process for doping an N-type impurity into the second N-type well 1324. The first N-type element 312 and the second N-type element 314 may be formed at the same time. However, the present disclosure is not limited thereto. In embodiments, the manufacturing method for the semiconductor circuit may comprise anneal processes for diffusing the impurities.

FIG. 1B illustrates an equivalent circuit of the electrostatic discharge protection circuit 102.

Referring to FIG. 1A and FIG. 1B, the electrostatic discharge protection circuit 102 comprises diodes, such as a first diode 116 and a second diode 118. An N-type semiconductor of the first diode 116 may comprise the N-type region 306 and the second N-type element 314. A P-type semiconductor of the first diode 116 may comprise the first P-type element 208. An N-type semiconductor of the second diode 118 may comprise the first N-type element 312. A P-type semiconductor of the second diode 118 may comprise the P-type well 204 and the second P-type element 210. The first diode 116 is electrically connected between the signal input terminal VCCQ and the conductive pad DQ. The second diode 118 is electrically connected between the ground terminal VSSQ and the conductive pad DQ. The conductive pad DQ is electrically connected between the first P-type element 208 (anode) of the first diode 116 and the first N-type element 312 (cathode) of the second diode 118.

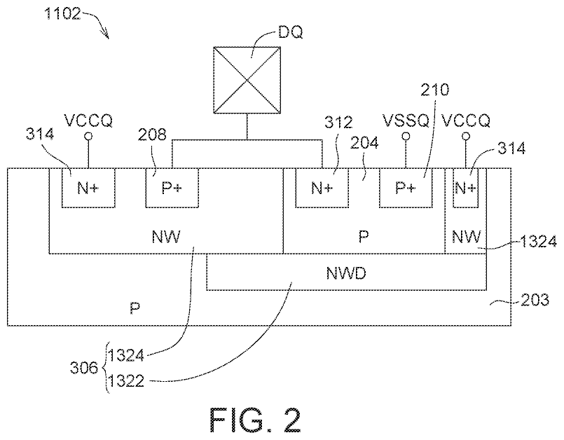

FIG. 2 is referred to, which illustrates an electrostatic discharge protection circuit 1102 of a semiconductor circuit and a manufacturing method for which in another embodiment. The embodiment shown in FIG. 2 is different from the embodiment shown in FIG. 1A in that the first N-type well 1322 under the P-type well 204 is adjoined with a portion of the lower surface of the second N-type well 1324. An equivalent circuit of the electrostatic discharge protection circuit 1102 may be similar with the equivalent circuit as shown in FIG. 1B.

In embodiments, the electrostatic discharge protection circuit can be used for protecting an internal circuit of the semiconductor circuit from an electrostatic discharge that would cause damage to the internal circuit.

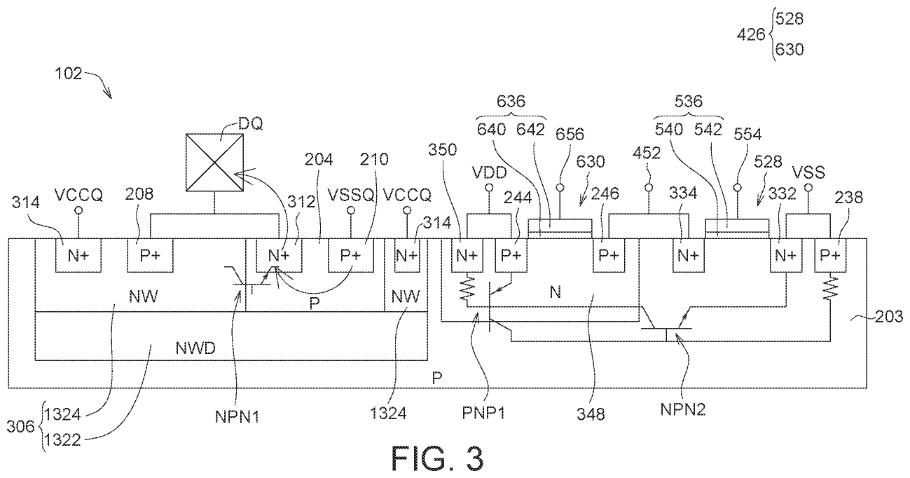

FIG. 3 illustrates a semiconductor circuit in an embodiment. The semiconductor circuit may comprise the electrostatic discharge protection circuit 102 and an internal circuit 426. The internal circuit 426 may comprise transistors, such as an N-type transistor 528 and a P-type transistor 630. The internal circuit 426 may comprise a CMOS. The CMOS may comprise the N-type transistor 528 (such as NMOS) and the P-type transistor 630 (such as PMOS).

The N-type transistor 528 may comprise a first N-type source/drain 332, a second N-type source/drain 334, the P-type region 203 and a gate structure 536. The first N-type source/drain 332 and the second N-type source/drain 334 may be formed in the P-type region 203 by an implanting process. The first N-type source/drain 332 and the second N-type source/drain 334 may be N-type impurity heavily doped source/drain. One of the first N-type source/drain 332 and the second N-type source/drain 334 is a source. The other of the first N-type source/drain 332 and the second N-type source/drain 334 is a drain. A third P-type element 238 may be formed in the P-type region 203. A P-type dopant concentration of the third P-type element 238 may be higher than a P-type dopant concentration of the P-type region 203. The third P-type element 238 may be a P-type impurity heavily doped (P+) element. The gate structure 536 may comprise a gate dielectric layer 540 and a gate electrode layer 542. The gate dielectric layer 540 may be formed on the P-type region 203 between the first N-type source/drain 332 and the second N-type source/drain 334. The gate electrode layer 542 is formed on the gate dielectric layer 540.

The P-type transistor 630 may comprise a first P-type source/drain 244, a second P-type source/drain 246, a gate structure 636 and an N-type well 348. The first P-type source/drain 244 and the second P-type source/drain 246 may be formed in the N-type well 348 by an implanting process. The first P-type source/drain 244 and the second P-type source/drain 246 may be P-type impurity heavily doped source/drain. One of the first P-type source/drain 244 and the second P-type source/drain 246 is a source. The other of the first P-type source/drain 244 and the second P-type source/drain 246 is a drain. A third N-type element 350 may be formed in the N-type well 348. An N-type dopant concentration of the third N-type element 350 may be higher than an N-type dopant concentration of the N-type well 348. The third N-type element 350 may be an N-type impurity heavily doped (N+) element. The gate structure 636 may comprise a gate dielectric layer 640 and a gate electrode layer 642. The gate dielectric layer 640 may be formed on the N-type well 348 between the first P-type source/drain 244 and the second P-type source/drain 246. The gate electrode layer 642 is formed on the gate dielectric layer 640.

The N-type region 306 of the electrostatic discharge protection circuit 102 may be separated from the N-type well 348 of the P-type transistor 630 of the internal circuit 426 by the P-type region 203.

The first N-type source/drain 332 of the N-type transistor 528 and the third P-type element 238 may be electrically connected to a around terminal VSS. The first P-type source/drain 244 of the P-type transistor 630 and the third N-type element 350 may be electrically connected to a signal input terminal VDD. The second N-type source/drain 334 of the N-type transistor 528 and the second P-type source/drain 246 of the P-type transistor 630 may be electrically connected to a signal output terminal 452. The gate structure 536 of the N-type transistor 528 may be electrically connected to a signal terminal 554. The gate structure 636 of the P-type transistor 630 may be electrically connected to a signal terminal 656.

In an embodiment, the signal input terminal VDD of the internal circuit 426 and the signal input terminal VCCQ of the electrostatic discharge protection circuit 102 are a common signal input terminal. The ground terminal VSS of the internal circuit 426 and the ground terminal VSSQ of the electrostatic discharge protection circuit 102 are a common ground terminal. However, the present disclosure is not limited thereto.

In a latch-up test, a negative current test is performed by applying a negative voltage to the conductive pad DQ, which extracts a current from the ground terminal VSSQ, and causes turning on of a parasitic bipolar junction transistor NPN1. The parasitic bipolar junction transistor NPN1 may be formed by the first N-type element 312, the P-type well 204 and the N-type region 306. The parasitic bipolar junction transistor NPN1 in the electrostatic discharge protection circuit 102 is independent from the internal circuit 426, and therefore would not cause a latch-up effect to the internal circuit 426.

In another embodiment, the electrostatic discharge protection circuit 102 of the semiconductor circuit is replaced by the electrostatic discharge protection circuit 1102 as shown in FIG. 2. In a latch-up test, a negative current test is performed by applying a negative voltage to the conductive pad DQ, which extracts a current from the ground terminal VSSQ, and causes turning on of a parasitic bipolar junction transistor NPN1. The parasitic bipolar junction transistor NPN1 may be formed by the first N-type element 312, the P-type well 204 and the N-type region 306. The parasitic bipolar junction transistor NPN1 in the electrostatic discharge protection circuit 1102 is independent from the internal circuit 426, and therefore would not cause a latch-up effect to the internal circuit 426.

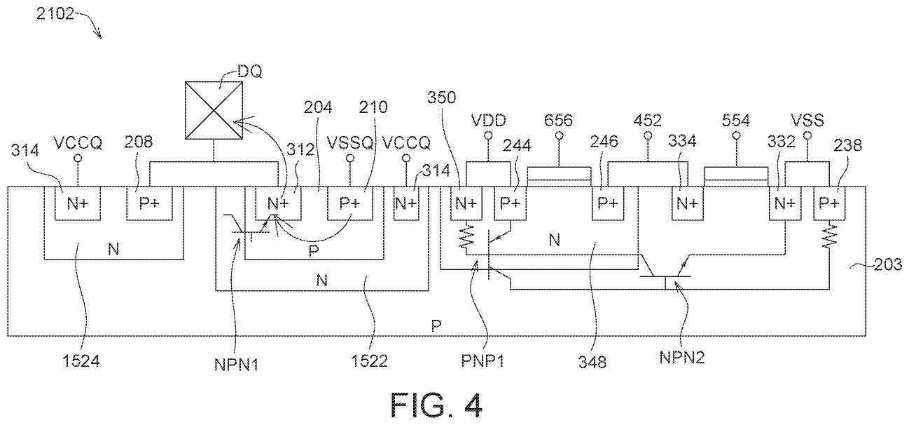

FIG. 4 illustrates a semiconductor circuit in a comparative example, which is different from the semiconductor circuit in the embodiment shown in FIG. 3 with the following description. An electrostatic discharge protection circuit 2102 has a first N-type part 1522 and a second N-type part 1524. The P-type well 204 and the second N-type element 314 are in the first N-type part 1522. The first P-type element 208 and the second N-type element 314 are in the second N-type part 1524. The first N-type part 1522 and the second N-type part 1524 are separated from each other by the P-type region 203. An additional layout area is required for the P-type region 203 used for separating the first N-type part 1522 and the second N-type part 1524. Therefore, compared to the comparative example in FIG. 4, the semiconductor circuit in the embodiment shown in FIG. 3 occupies a smaller layout area. The electrostatic discharge protection circuit 102 in the embodiment shown in FIG. 1A and FIG. 3, and the electrostatic discharge protection circuit 1102 in the embodiment shown in FIG. 2 occupy a smaller layout area, compared to the electrostatic discharge protection circuit 2102 in the comparative example in FIG. 4.

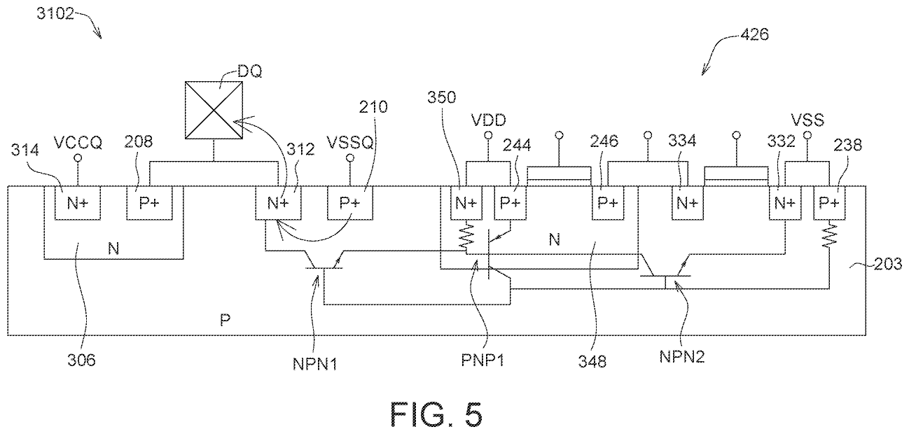

FIG. 5 illustrates a semiconductor circuit in another comparative example, which is different from the semiconductor circuit in the embodiment shown in FIG. 3 in that an electrostatic discharge protection circuit 3102 have the first N-type element 312 and the second P-type element 210 formed in the P-type region 203. In a latch-up test, a negative current test is performed by applying a negative voltage to the conductive pad DQ, which extracts a current from the ground terminal VSSQ, and causes turning on of a parasitic bipolar junction transistor NPN1. The parasitic bipolar junction transistor NPN1 causes turning on of a parasitic bipolar junction transistor PNP1 and a parasitic bipolar junction transistor NPN2 in the internal circuit 426, and a latch-up is formed. The parasitic bipolar junction transistor NPN1 may be formed by the first N-type element 312, the P-type region 203 and the N-type well 348. The parasitic bipolar junction transistor PNP1 may be formed by the first P-type source/drain 244, the N-type well 348 and the P-type region 203. The parasitic bipolar junction transistor NPN2 may be formed by the N-type well 348, the P-type region 203 and the first N-type source/drain 332.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor circuit, comprising an electrostatic discharge protection circuit, wherein the electrostatic discharge protection circuit comprises:
an N-type region;
a P-type well in the N-type region;
a first P-type element in the N-type region, wherein the N-type region is continuously connected between the P-type well and the first P-type element; and
a first N-type element in the P-type well.

2. The semiconductor circuit according to claim 1, wherein the P-type well has a profile defined by the N-type region.

3. The semiconductor circuit according to claim 1, wherein the N-type region comprises:
a first N-type well; and
a second N-type well electrically connected with the first N-type well.

4. The semiconductor circuit according to claim 3, wherein the second N-type well is on a sidewall of the P-type well.

5. The semiconductor circuit according to claim 3, wherein the first N-type well is under the P-type well.

6. The semiconductor circuit according to claim 3, wherein the first N-type well has an N-type impurity concentration higher than an N-type impurity concentration of the second N-type well.

7. The semiconductor circuit according to claim 3, further comprising a P-type region, wherein the first N-type well and the second N-type well are in the P-type region.

8. The semiconductor circuit according to claim 1, further comprising a conductive pad electrically connected to the first P-type element and the first N-type element.

9. The semiconductor circuit according to claim 1, wherein the electrostatic discharge protection circuit comprises:
a first diode comprising the N-type region and the first P-type element; and
a second diode comprising the P-type well and the first N-type element.

10. The semiconductor circuit according to claim 9, further comprising a signal input terminal, a conductive pad and a ground terminal, wherein the first diode is electrically connected between the signal input terminal and the conductive pad, the second diode is electrically connected between the ground terminal and the conductive pad.

11. The semiconductor circuit according to claim 1, further comprising a P-type region and an internal circuit, wherein the N-type region is in the P-type region, the internal circuit comprises a P-type transistor, wherein the P-type transistor comprises:
an N-type well in the P-type region;
a first P-type source/drain and a second P-type source/drain; and
a gate structure on the N-type well between the first P-type source/drain and the second P-type source/drain.

12. The semiconductor circuit according to claim 1, further comprising an internal circuit, wherein the internal circuit comprises an N-type transistor, the N-type transistor comprises:
a P-type region:
a first N-type source/drain and a second N-type source/drain; and
a gate structure on the P-type region between the first N-type source/drain and the second N-type source/drain.
wherein the N-type region is in the P-type region.

13. A manufacturing method for a semiconductor circuit, comprising:
forming a N-type region;
forming a P-type well, wherein the P-type well is in the N-type region;
forming a first P-type element in the N-type region; and
forming a first N-type element in the P-type well, wherein
the semiconductor circuit comprises an electrostatic discharge protection circuit, the electrostatic discharge protection circuit comprises the N-type region, the P-type well, the first P-type element and the first N-type element, the N-type region is continuously connected between the P-type well and the first P-type element.

14. The manufacturing method for the semiconductor circuit according to claim 13, wherein the N-type region is formed by a method comprising:
forming a first N-type well by performing an implanting process; and
forming a second N-type well by performing another implanting process.

15. The manufacturing method for the semiconductor circuit according to claim 14, wherein the first P-type element is formed in the second N-type well.

16. The manufacturing method for the semiconductor circuit according to claim 14, wherein the first N-type well and the second N-type well are formed in a P-type region.

17. The manufacturing method for the semiconductor circuit according to claim 14, wherein the second N-type well is on the first N-type well.

18. The manufacturing method for the semiconductor circuit according to claim 14, wherein the P-type well has a profile defined by the first N-type well and the second N-type well.

19. The manufacturing method for the semiconductor circuit according to claim 13, further comprising:
forming an N-type well in a P-type region;
forming a first P-type source/drain and a second P-type source/drain in the N-type well; and
forming a gate structure on the N-type well between the first P-type source/drain and the second P-type source/drain, wherein the semiconductor circuit comprises a P-type transistor, the P-type transistor comprises the N-type well, the first P-type source/drain, the second P-type source/drain and the gate structure.

20. The manufacturing method for the semiconductor circuit according to claim 13, further comprising:
forming a first N-type source/drain and a second N-type source/drain in a P-type region; and
forming a gate structure on the P-type region between the first N-type source/drain and the second N-type source/drain, wherein the semiconductor circuit further comprises an N-type transistor, the N-type transistor comprises the P-type reaion, the first N-type source/drain, the second N-type source/drain and the gate structure,
wherein the N-type region is formed in the P-type region.
